(19) United States
(12) Patent Application Publication
(10) Pub. No.: US 2021/0193844 A1
(43) Pub. Date: Jun. 24, 2021

(54) STRAIN BASED PERFORMANCE ENHANCEMENT USING SELECTIVE METAL OXIDATION INSIDE GATE

(71) Applicant: Intel Corporation, Santa Clara, CA (US)

(72) Inventors: Rahul RAMASWAMY, Portland, OR (US); Hsu-Yu CHANG, Hillsboro, OR (US); Babak FALLAHAZAD, Portland, OR (US); Hsiao-Yuan WANG, Portland, OR (US); Ting CHANG, Portland, OR (US); Tanuj TRIVEDI, Hillsboro, OR (US); Jeong Dong KIM, Scappoose, OR (US); Nidhi NIDHI, Hillsboro, OR (US); Walid M. HAFEZ, Portland, OR (US)

(21) Appl. No.: 16/725,161

(22) Filed: Dec. 23, 2019

(51) Int. Cl. H01L 29/786; H01L 29/78; H01L 29/423; H01L 29/10; H01L 29/66

(52) U.S. Cl. CPC H01L 29/78696; H01L 29/785; H01L 29/66795; H01L 29/1041; H01L 29/42392

(57) ABSTRACT

Embodiments disclosed herein include semiconductor devices and methods of forming such devices. In an embodiment, a semiconductor device comprises a source, a drain, and a semiconductor channel between the source and the drain. In an embodiment, the semiconductor channel has a non-uniform strain through a thickness of the semiconductor channel. In an embodiment, the semiconductor device further comprises a gate stack around the semiconductor channel.

### TECHNICAL FIELD

Embodiments of the present disclosure relate to semiconductor devices, and more particularly to nanoribbon and nanowire transistor devices with strained channel regions.

### BACKGROUND

As integrated device manufacturers continue to shrink the feature sizes of transistor devices to achieve greater circuit density and higher performance, there is a need to manage transistor drive currents while reducing short-channel effects, parasitic capacitance, and off-state leakage in next-generation devices. Non-planar transistors, such as fin and nanowire-based devices, enable improved control of short channel effects. For example, in nanowire-based transistors the gate stack wraps around the full perimeter of the nanowire, enabling fuller depletion in the channel region, and reducing short-channel effects due to steeper sub-threshold current swing (SS) and smaller drain induced barrier lowering (DIBL).

In order to further improve performance of non-planar transistors, strain engineering is often implemented. Particularly, strain is induced in the source and the drain. This is done by growing semiconductor materials in the source and the drain that has a lattice mismatch with the semiconductor material of the channel between the source and the drain. Additional solutions to enhance the performance of non-planar transistors includes modifying the channel length or reducing the gate dielectric thickness to provide improved channel control.

### BRIEF DESCRIPTION OF THE DRAWINGS

FIG. 1A is a cross-sectional illustration of a nanoribbon transistor with strained channels, in accordance with an embodiment.

FIG. 1B is a cross-sectional illustration of the nanoribbon transistor in FIG. 1A along line B-B′, in accordance with an embodiment.

FIG. 2A is a cross-sectional illustration of a strained nanoribbon channel, in accordance with an embodiment.

FIG. 2B is a graph plotting the strain through a thickness of the nanoribbon channel in FIG. 2A, in accordance with an embodiment.

FIG. 2C is a cross-sectional illustration of a strained nanoribbon channel, in accordance with an additional embodiment.

FIG. 2D is a graph plotting the strain through a thickness of the nanoribbon channel in FIG. 2C, in accordance with an embodiment.

FIG. 3A is a cross-sectional illustration of a workfunction metal and a gate dielectric around a nanoribbon channel, in accordance with an embodiment.

FIG. 3B is a graph of the relative oxygen concentration along a line through the workfunction metal and the gate dielectric, in accordance with an embodiment.

FIG. 4 is a cross-sectional illustration of a nanoribbon transistor where not all nanoribbon channels are strained, in accordance with an embodiment.

FIG. 5A is a cross-sectional illustration of a semiconductor device with a first nanoribbon transistor and a second nanoribbon transistor with non-uniform channel lengths, in accordance with an embodiment.

FIG. 5B is a cross-sectional illustration of a semiconductor device where a first nanoribbon transistor comprises a first workfunction metal, and a second nanoribbon transistor comprises a second workfunction metal, in accordance with an embodiment.

FIG. 5C is a cross-sectional illustration of a semiconductor device comprising vertically stacked nanoribbon transistors, in accordance with an embodiment.

FIGS. 6A-6T are illustrations of a process for forming a semiconductor device with a nanoribbon transistor that comprises a strained channel, in accordance with an embodiment.

FIGS. 7A-7D are cross-sectional illustrations of a process for forming a semiconductor device with a nanoribbon transistor that comprises strained and unstrained channels, in accordance with an embodiment.

FIGS. 8A-8D are cross-sectional illustrations of a process for forming a semiconductor device with a first nanoribbon transistor that has a first number of strained channels, and a second nanoribbon transistor that has a second number of strained channels, in accordance with an embodiment.

FIG. 9 illustrates a computing device in accordance with one implementation of an embodiment of the disclosure.

FIG. 10 is an interposer implementing one or more embodiments of the disclosure.

### EMBODIMENTS OF THE PRESENT DISCLOSURE

Described herein are nanoribbon and nanowire transistor devices with strained channel regions, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Nanoribbon devices are described in greater detail below. However, it is to be appreciated that substantially similar devices may be formed with nanowire channels. A nanowire device may include devices where the channel has a width dimension and a thickness dimension that are substantially similar, whereas a nanoribbon device may include a channel that has a width dimension that is substantially larger or substantially smaller than a thickness dimension. As used herein, “high-voltage” may refer to voltages of approximately 1.0V or higher.

As noted above, improvements in the performance of transistors may be achieved by inducing strain in the source and drain of the transistor. However, embodiments disclosed herein may also include nanoribbon or nanowire transistors that include strained channels. That is, the channel that is surrounded by the gate structure may be strained in order to provide improved performance. Particularly, the strain induced in embodiments disclosed herein may be referred to as radial strain. A radial strain is distinct from an axial strain. For example, an axial strain may refer to a strain that is oriented along an axis parallel to the length direction of the channel, whereas the radial strain is oriented substantially perpendicular to centerline along the length direction of the channel. Embodiments may be characterized by a maximum tensile strain in the channel that is approximately 0.5% or greater. As used herein “approximately” may refer to a value that is within 20% of the recited value. For example, approximately 0.5% may refer to a range between 0.4% and 0.6%.

In an embodiment, the radial strain in the channel is induced by the annealing of a sacrificial polymer that is disposed around the workfunction metal. The annealing process shrinks the polymer and induces an outward force on the perimeter of the channel. This induces a radial tensile strain on the channel. In some embodiments, the annealing process may be implemented in an oxygen ambient. As such, some embodiments may also include the presence of oxygen in the workfunction metal. That is, the workfunction metal may be referred to as being selectively oxidized.

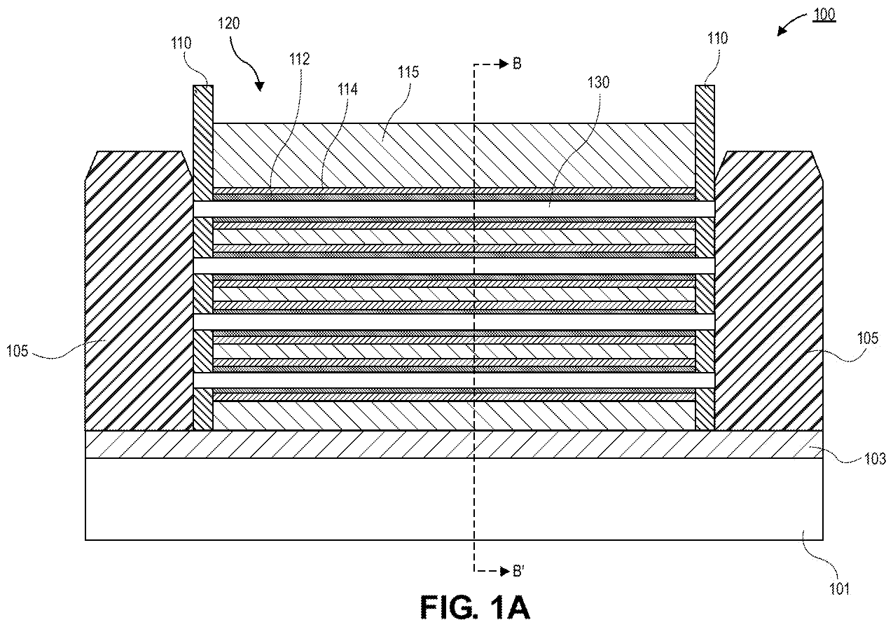

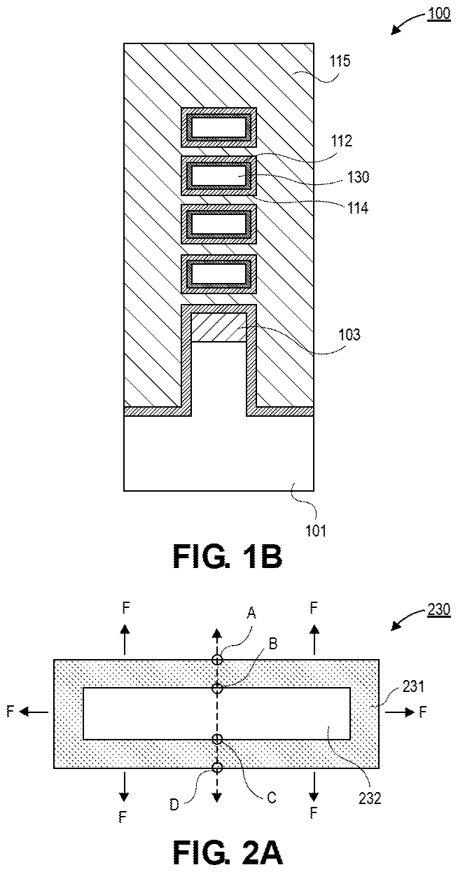

Referring now to FIGS. 1A and 1B, a cross-sectional illustration of a nanoribbon transistor 100 and a cross-section along line B-B′ in FIG. 1A are shown, respectively, in accordance with an embodiment. The nanoribbon transistor 100 may be disposed over a substrate 101. In an embodiment, the substrate 101, may include a semiconductor substrate and an isolation layer 103 over the semiconductor substrate 101. In an embodiment, the underlying semiconductor substrate 101 represents a general workpiece object used to manufacture integrated circuits. The semiconductor substrate 101 often includes a wafer or other piece of silicon or another semiconductor material. Suitable semiconductor substrates 101 include, but are not limited to, single crystal silicon, polycrystalline silicon and silicon on insulator (SOI), as well as similar substrates formed of other semiconductor materials, such as substrates including germanium, carbon, or group III-V materials.

The nanoribbon transistor 100 may comprise a source 105 and drain 105. In some embodiments, the source or drain may be referred to as an S/D region 105 to represent that the region may either be a source 105 or a drain 105. In an embodiment, the S/D regions 105 may comprise an epitaxially grown semiconductor material. The S/D regions 105 may comprise a silicon alloy. In some implementations, the S/D regions 105 comprise a silicon alloy that may be in-situ doped silicon germanium, in-situ doped silicon carbide, or in-situ doped silicon. In alternate implementations, other silicon alloys may be used. For instance, alternate silicon alloy materials that may be used include, but are not limited to, nickel silicide, titanium silicide, cobalt silicide, and possibly may be doped with one or more of boron and/or aluminum. In other embodiments, the S/D regions 105 may comprise alternative semiconductor materials (e.g., semiconductors comprising group III-V elements and alloys thereof) or conductive materials.

In an embodiment, a plurality of semiconductor channels 130 may extend between the pair of S/D regions 105. The semiconductor channels 130 may be arranged in a vertical stack. Four semiconductor channels 130 are illustrated in FIG. 1A, but it is to be appreciated that the nanoribbon transistor 100 may include one or more semiconductor channels 130. The semiconductor channels 130 may comprise any suitable semiconductor materials. For example, the semiconductor channels 130 may comprise silicon or group III-V materials. In an embodiment, the semiconductor channels 130 may be nanoribbon channels or nanowire channels. For simplicity, the semiconductor channels 130 will be referred to herein as nanoribbon channels 130.

In an embodiment, a gate structure 120 may be disposed over the nanoribbon channels 130. The gate structure 120 may comprise spacers 110, a gate dielectric 112, a gate metal 114 and a fill metal 115. The nanoribbon channels 130 may pass through the spacers 110 to contact the S/D regions 105.

In an embodiment, the gate dielectric 112 may surround the nanoribbon channels 130. The material (or materials) chosen for the gate dielectric 112 may be any suitable high dielectric constant materials. For example, the gate dielectric 112 may be, for example, any suitable oxide such as silicon dioxide or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In an embodiment, the gate dielectric 112 may also be subject to an annealing process to improve performance.

In an embodiment, the gate metal 114 wraps around the gate dielectric 112 to provide gate all around (GAA) control of the nanoribbon channel 130. The gate metal 114 may sometimes be referred to as a workfunction metal. That is, the material chosen for the gate metal 114 may be dependent on the workfunction of the material in order to provide a desired voltage threshold (VT) tuning for the nanoribbon transistor 100. For example, when the gate metal 114 will serve as an N-type workfunction metal, the gate metal 114 preferably has a workfunction that is between about 3.9 eV and about 4.2 eV. N-type materials that may be used to form the gate metal 114 include, but are not limited to, hafnium, zirconium, titanium, tantalum, aluminum, and metal carbides that include these elements, e.g., titanium carbide, zirconium carbide, tantalum carbide, hafnium carbide and aluminum carbide. Alternatively, when the gate metal 114 will serve as a P-type workfunction metal, the gate metal 114 preferable has a workfunction that is between about 4.9 eV and about 5.2 eV. P-type materials that may be used to form the gate metal 114 include, but are not limited to, ruthenium, palladium, platinum, cobalt, nickel, and conductive metal oxides, e.g., ruthenium oxide. In an embodiment, a fill metal 115 (e.g., tungsten) may be disposed over the gate metal 114.

In an embodiment, portions of the nanoribbon channels 130 that are surrounded by the gate structure 120 may be strained. Straining the nanoribbon channels 130 increases the carrier mobility within the nanoribbon channels 130 and improves efficiency. In an embodiment, the strain in the nanoribbon channels 130 is a tensile strain. In a particular embodiment, the tensile strain is a radial strain on the nanoribbon channels 130. That is, the nanoribbon channels 130 are strained by expanding the cross-section of the nanoribbon channels 130 shown in FIG. 1B as opposed to extending the length of the nanoribbon channels 130 between the S/D regions 105.

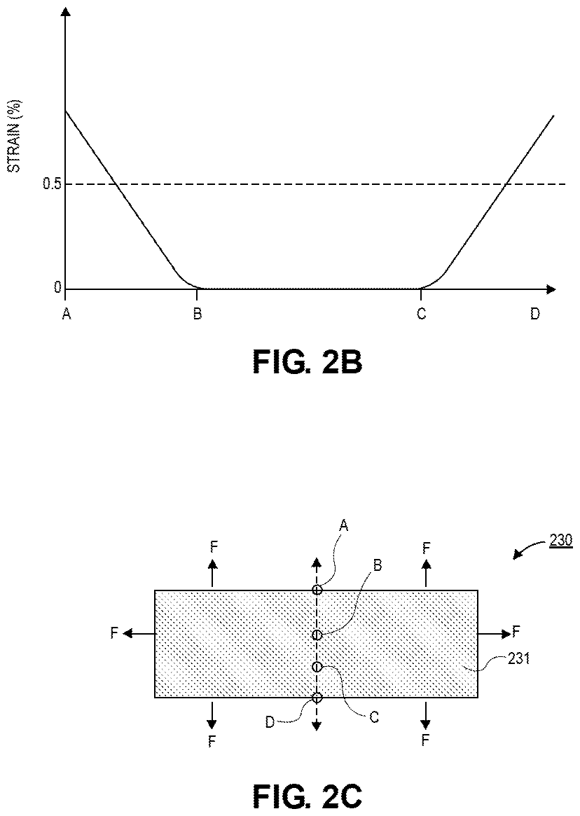

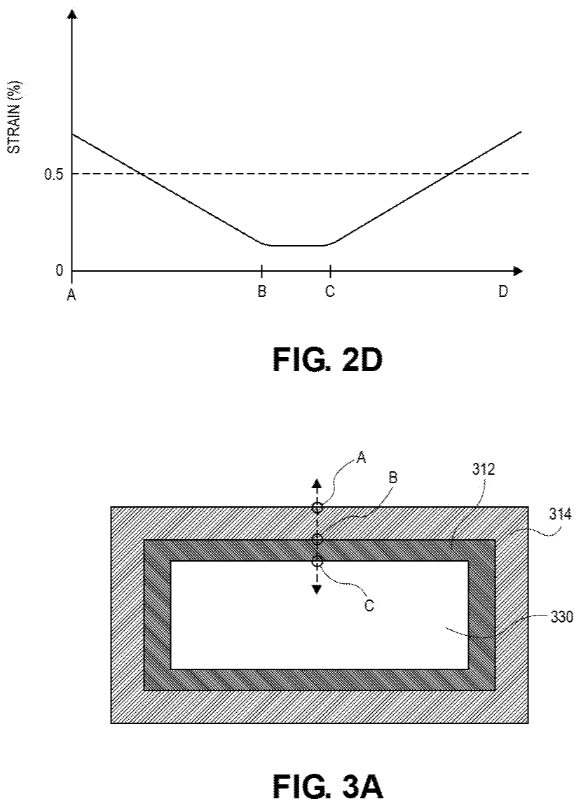

Referring now to FIG. 2A, a cross-sectional illustration of a single nanoribbon channel 230 is shown, in accordance with an embodiment. As shown, a radial force F is applied around the outer perimeter of the nanoribbon channel 230. A description of how the force F is applied is provided in greater detail below. The radial force F results in portions of the nanoribbon channel 230 being strained (as indicated by the outer ring depicting a strained region 231). The strained region 231 may surround the perimeter of the nanoribbon channel 230. As shown, the strained region 231 may not occupy the entire volume of the nanoribbon channel 230. For example, a substantially unstrained region 232 (e.g., with a strain of approximately 0%) may remain at the core of the nanoribbon channel 230.

In FIG. 2A the strained region 231 is shown as having a uniform shading. However, it is to be appreciated that the strain distribution within the strained region 231 may be non-uniform. An example of a possible strain distribution across a thickness of the nanoribbon channel 230 is shown in FIG. 2B

As shown, the strain between points A and B along the line through the thickness of the nanoribbon channel 230 may have a decreasing slope. That is, larger strains may be exhibited closer to the surface of the nanoribbon channel 230. At point B, the strain may be approximately 0%. That is, portions of the nanoribbon channel 230 between points B and C may be an unstrained region 232. Between points C and D, the strain may have a positive slope. In an embodiment, the nanoribbon channel 230 may exhibit a maximum strain that is approximately 0.5% or greater.

Referring now to FIG. 2C, a cross-sectional illustration of a nanoribbon channel 230 is shown, in accordance with an additional embodiment. In the illustrated embodiment, the entire volume of the nanoribbon channel 230 is a strained region 231. That is, substantially all of the volume of the nanoribbon channel 230 may be strained as the result of a radial force F.

FIG. 2D is a graph of the strain distribution across a thickness of the nanoribbon channel 230. As shown, in some embodiments, the strain distribution may have a negative slope between points A and B, the strain distribution may have no slope between points B and C, and the strain distribution may have a positive slope between points C and D. In the illustrated embodiment, the strain between points B and C may be greater than 0%. The length between points B and C may be any length. In some embodiments, the length between points B and C may be approximately 0 nm. That is, the slope of the strain distribution may switch from negative to positive at a single point. Similar to the embodiment illustrated in FIG. 2A, a maximum strain in the nanoribbon channel 230 of FIG. 2C may be approximately 0.5% or greater.

It is to be appreciated that strain measurements of the nanoribbon channels 230 may be obtained with a variety of different analytical techniques. One exemplary analytical technique to determine the strain distribution within a nanoribbon channel 230 may include the use of TEM imaging and analysis. Additionally, the strain distributions illustrated in FIGS. 2B and 2D are exemplary in nature. It is to be appreciated that other strain distributions may occur through a thickness of the nanoribbon channels 230.

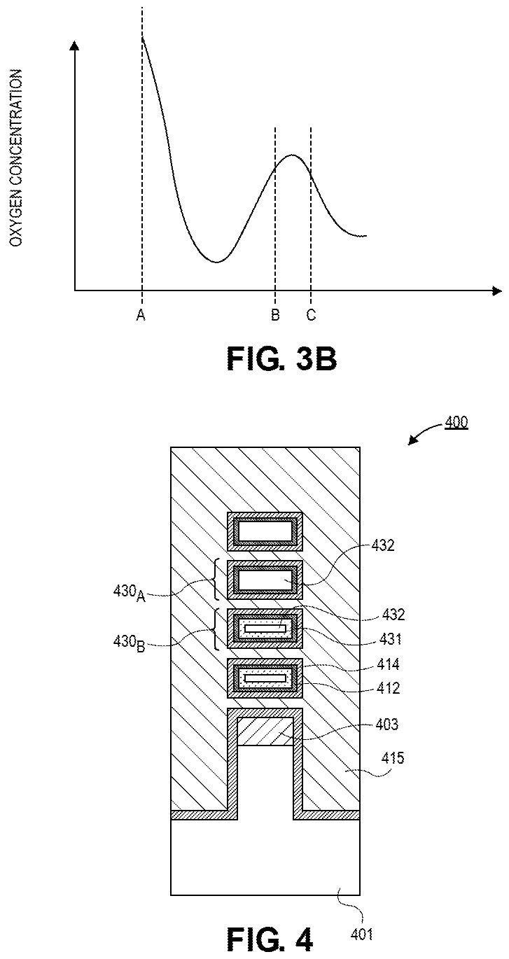

Referring now to FIG. 3A, a cross-sectional illustration of a nanoribbon channel 330 that is surrounded by a gate dielectric 312 and a gate metal 314 is shown, in accordance with an embodiment. In an embodiment, a line through a thickness of the gate metal 314, the gate dielectric 312, and into the nanoribbon channel 330 is shown. Points A, B, and C, along the line are indicated for reference with respect to the graph of relative oxygen concentration in FIG. 3B.

As shown in FIG. 3B, the gate metal 314 may comprise oxygen. In a particular embodiment, the oxygen concentration through a thickness of the gate metal 314 (i.e., between points A and B) is a non-uniform concentration. That is, moving away from the outer surface of the gate metal 314 results in a decrease in the oxygen concentration in the gate metal 314. The oxygen concentration may then increase while approaching the interface with the gate dielectric 312 (i.e., at point B). This is because the gate dielectric 312 may comprise an oxide which serves as a source of oxygen that can diffuse into the gate metal 314. A local oxygen concentration peak may be present within the gate dielectric 312 (i.e., between points B and C), and the oxygen concentration may decrease entering into the nanoribbon channel 330 (i.e., past point C). The oxygen concentration graph illustrated in FIG. 3B is exemplary in nature, and embodiments may include an oxygen concentration graph with other features, depending on the structure and materials used for the nanoribbon transistor.

The relatively high concentration of oxygen in the gate metal 314 may be an artifact of processing used to induce strain in the nanoribbon channel 330. As will be described in greater detail below, a sacrificial polymer may be disposed around the gate metal 314 and annealed in an oxygen ambient in order to induce the strain in the nanoribbon channel 330. Such a process may result in the selective oxidation of the gate metal 314, particularly, the outer surfaces of the gate metal 314. As such, the oxygen concentration proximate to the outer surface of the gate metal 314 may be higher than an oxygen concentration within an internal volume of the gate metal 314 and/or at the surface of the gate metal 314 that interfaces with the gate dielectric 312.

While an oxygen concentration distribution such as the one described with respect to FIG. 3B may be present in some embodiments, it is to be appreciated that some embodiments described herein may not have such an oxygen concentration distribution. For example, the strain may be induced by an anneal of a sacrificial polymer that utilizes an inert ambient (e.g., nitrogen). In such instances, the selective oxidation of the gate metal 314 may be reduced or eliminated.

Referring now to FIG. 4, a cross-sectional illustration of a nanoribbon transistor 400 is shown, in accordance with an embodiment. The nanoribbon transistor 400 may comprise a substrate 401 and an isolation layer 403. A plurality of nanoribbon channels 430 may be arranged in a vertical stack. Individual ones of the nanoribbon channels 430 may be surrounded by a gate dielectric 412 and a gate metal 414. A fill metal 415 may surround the gate metal 414.

In an embodiment, first nanoribbon channels 430_{A} may have volumes that are substantially unstrained regions 432, and second nanoribbon channels 430_{B} may have volumes that comprise a strained region 431. In some embodiments, the second nanoribbon channels 430_{B} may have both a strained region 431 and an unstrained region 432 (similar to the embodiment shown in FIG. 2A) or only a strained region 431 (similar to the embodiment shown in FIG. 2C). That is, embodiments may include a nanoribbon transistor 400 that comprises nanoribbon channels 430 that do not have the same strain profile.

In an embodiment, the first nanoribbon channels 430_{A} may be located above the second nanoribbon channels 430_{B} (with respect to the substrate 401). While two first nanoribbon channels 430_{A} and 430_{B} are shown, it is to be appreciated that the number of first nanoribbon channels 430_{A} may be different than the number of second nanoribbon channels 430_{B}.

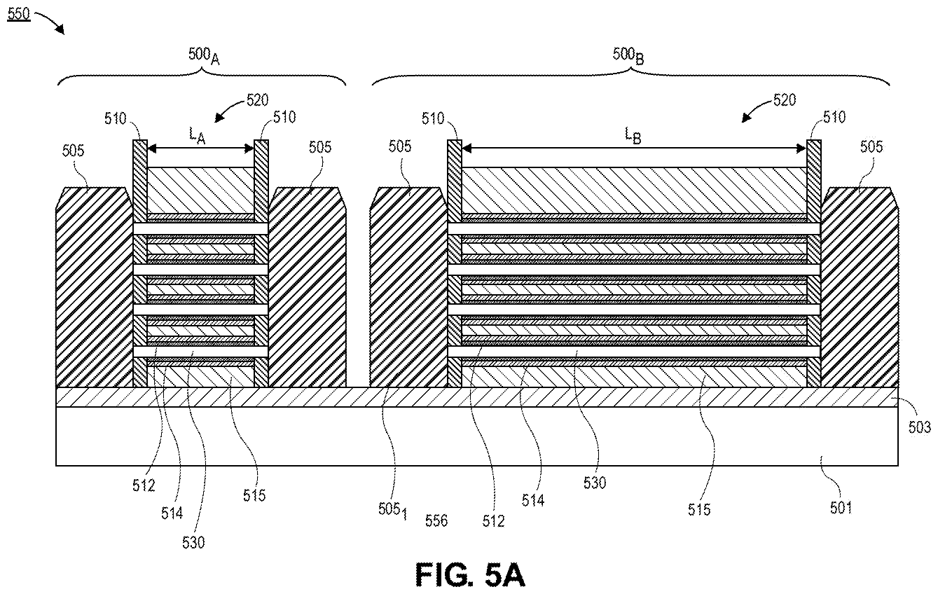

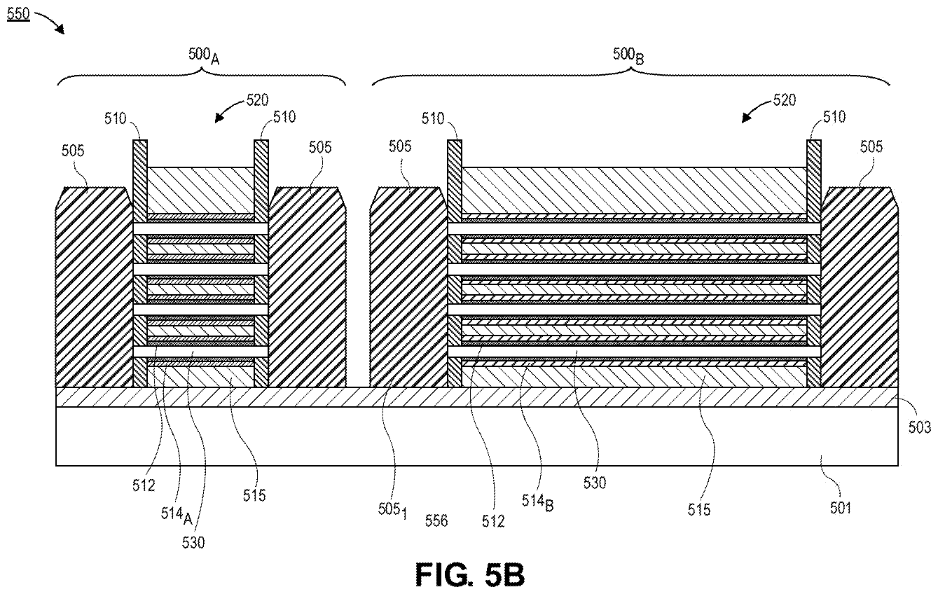

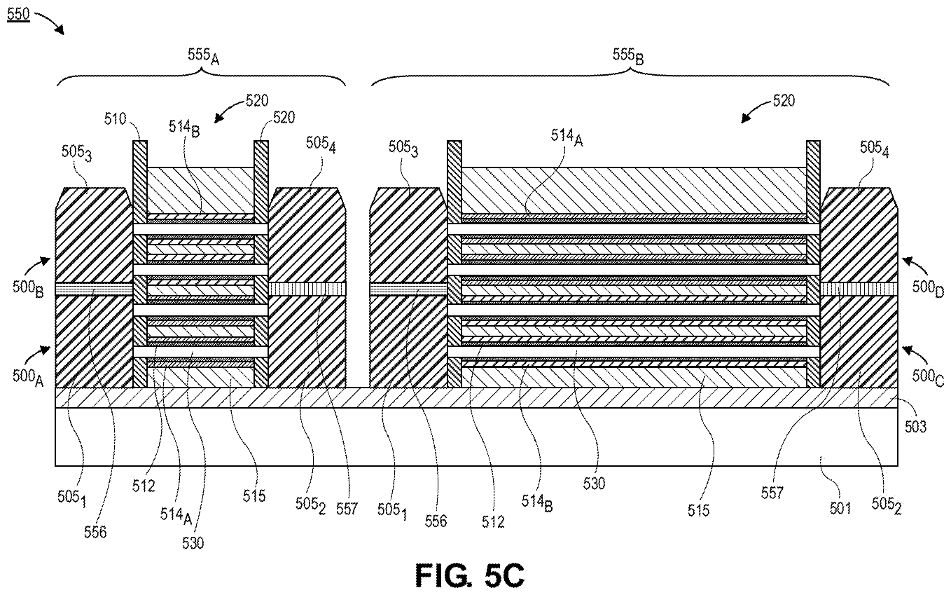

Referring now to FIG. 5A, a cross-sectional illustration of a semiconductor device 550 is shown, in accordance with an embodiment. The semiconductor device 550 may comprise a first transistor 500_{A} and a second transistor 500_{B}. The first transistor 500_{A} may have a first channel length L_{A} that is smaller than a second channel length L_{B} of the second transistor 500_{B}. For example, the first transistor 500_{A} may be a logic transistor and the second transistor 500_{B} may be suitable for high voltage applications (e.g., power management).

In an embodiment, the first transistor 500_{A} and the second transistor 500_{B} may comprise S/D regions 505 over a substrate 501 and an insulator 503. Nanoribbon channels 530 may extend between pairs of S/D regions 505. Each transistor 500_{A} and 500_{B} may comprise a gate structure 520. The gate structure 520 may comprise a gate dielectric 512, a gate metal 514, a fill metal 515, and spacers 510.

In an embodiment, one or both of the first transistor 500_{A} and the second transistor 500_{B} may comprise strained nanoribbon channels 530. The nanoribbon channels 530 may be strained similar to those described above with respect to FIGS. 2A and/or 2C. In some embodiments the nanoribbon channels 530 of the first transistor 500_{A} may have substantially the same strain distribution as the nanoribbon channels 530 of the second transistor 500_{B}. In other embodiments, the nanoribbon channels 530 of the first transistor 500_{A} may have a substantially different strain distribution than the nanoribbon channels 530 of the second transistor 500_{B}.

Referring now to FIG. 5B, a cross-sectional illustration of a semiconductor device 550 is shown, in accordance with an additional embodiment. The semiconductor device 550 in FIG. 5B may be substantially similar to the semiconductor device 550 in FIG. 5A, with the exception that a first gate metal 514_{A} in the first transistor 500_{A} is a different material than a second gate metal 514_{B} in the second transistor 500_{B}. For example, the first gate metal 514_{A} may be a P-type workfunction metal and the second gate metal 514_{B} may be an N-type workfunction metal.

Referring now to FIG. 5C, a cross-sectional illustration of a semiconductor device 550 is shown, in accordance with an additional embodiment. The semiconductor device 550 may include a first inverter 555_{A} and a second inverter 555_{B}. Each inverter may include a pair of vertically stacked nanoribbon transistors 500 with different conductivity types that share a gate structure 520. For example, the first inverter 555_{A} comprises nanoribbon transistors 500_{A} and 500_{B}. Nanoribbon transistor 500_{A} may be a P-type transistor with a P-type gate metal 514_{A}, and nanoribbon transistor 500_{B} may be an N-type transistor with an N-type gate metal 514_{B}. The gate metals 514_{A} and 514_{B} are electrically held at the same potential by the fill metal 515.

Nanoribbon transistor 500_{A} may utilize S/D regions 505₁ and 505₂, and nanoribbon transistor 500_{B} may utilize S/D regions 505₃ and 505₄. In an embodiment, S/D region 505₁ may be electrically isolated from S/D region 505₃ by an insulating layer 556, and S/D region 505₂ may be electrically coupled to S/D region 505₄ by a conducting layer 557.

The second inverter 555_{B} may have a similar stacked transistor configuration with a shared gate structure 520. For example, transistor 500_{C} is below transistor 500_{D}. In some embodiments, the conductivity types of the transistors 500 in the second inverter 555_{B} may be opposite of those in the first inverter 555_{A}. For example, transistor 500_{C} may be the opposite conductivity type of the bottom transistor 500_{A} in the first inverter 555_{A}, and transistor 500_{D} may be the opposite conductivity type of the top transistor 500_{B} in the first inverter 555_{A}. In other embodiments, the conductivity types of the first inverter 555_{A} may match the conductivity types of the second inverter 555_{B}.

In an embodiment, one or more of the nanoribbon channels 530 of the first inverter 555_{A} and/or the second inverter 555_{B} may be strained. In some embodiments, the nanoribbon channels 530 may have both a strained region and an unstrained region (similar to the embodiment shown in FIG. 2A) or only a strained region (similar to the embodiment shown in FIG. 2C).

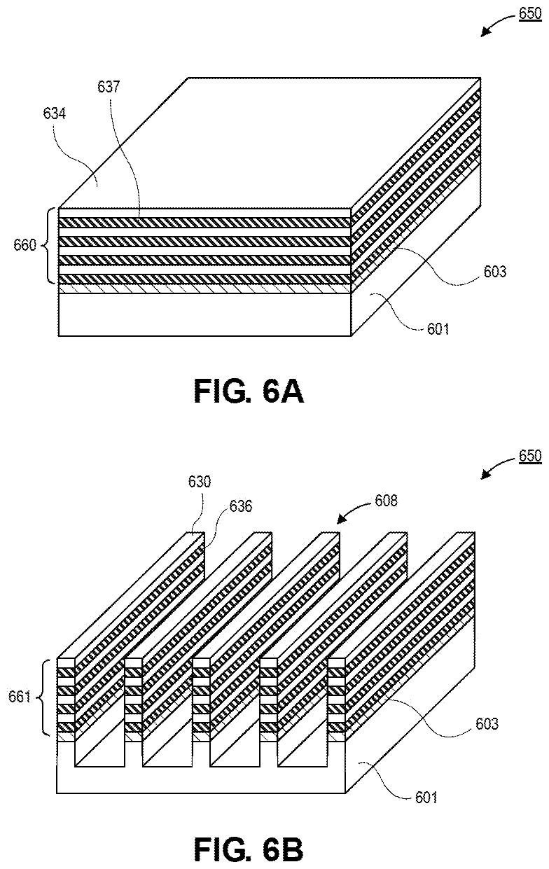

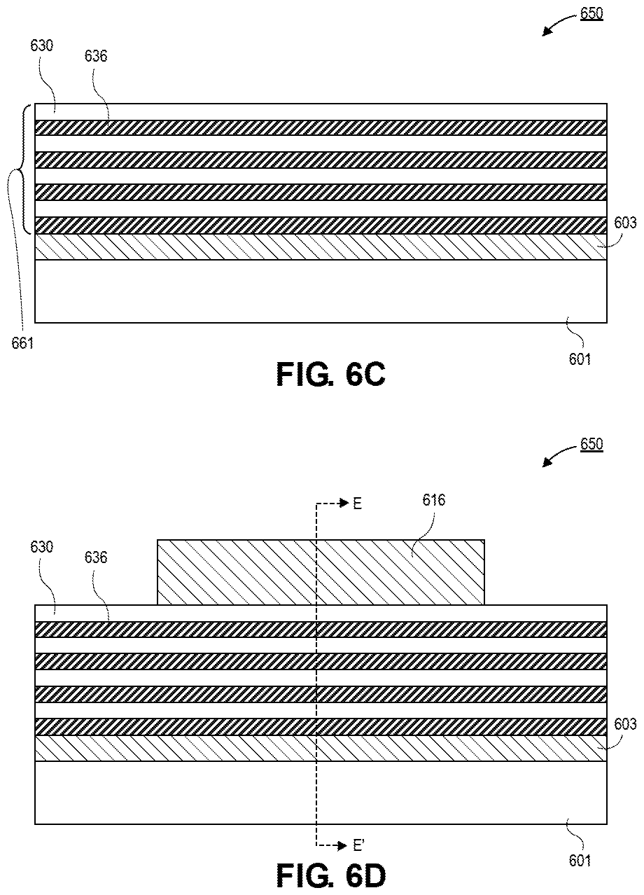

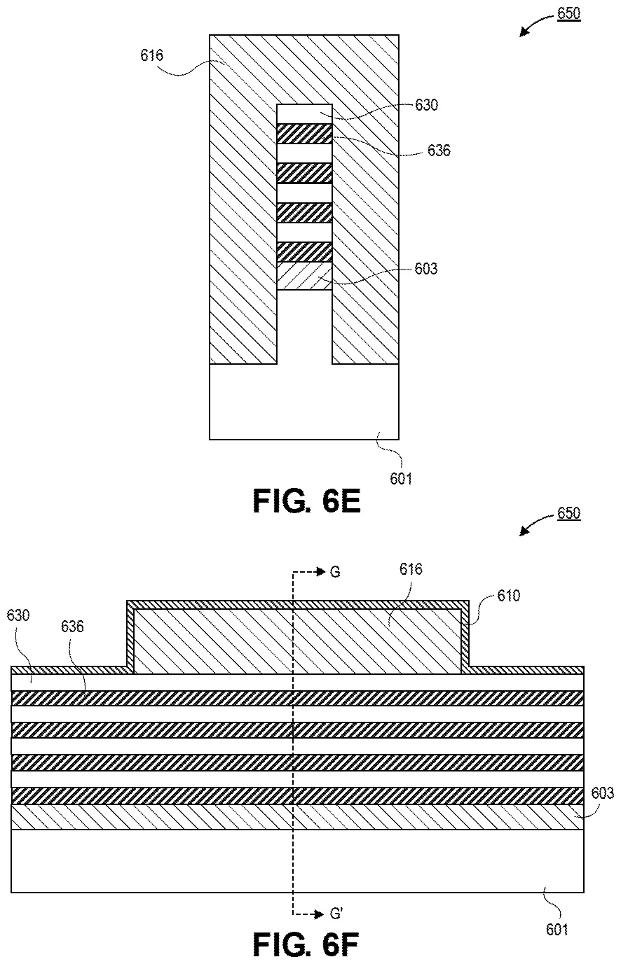

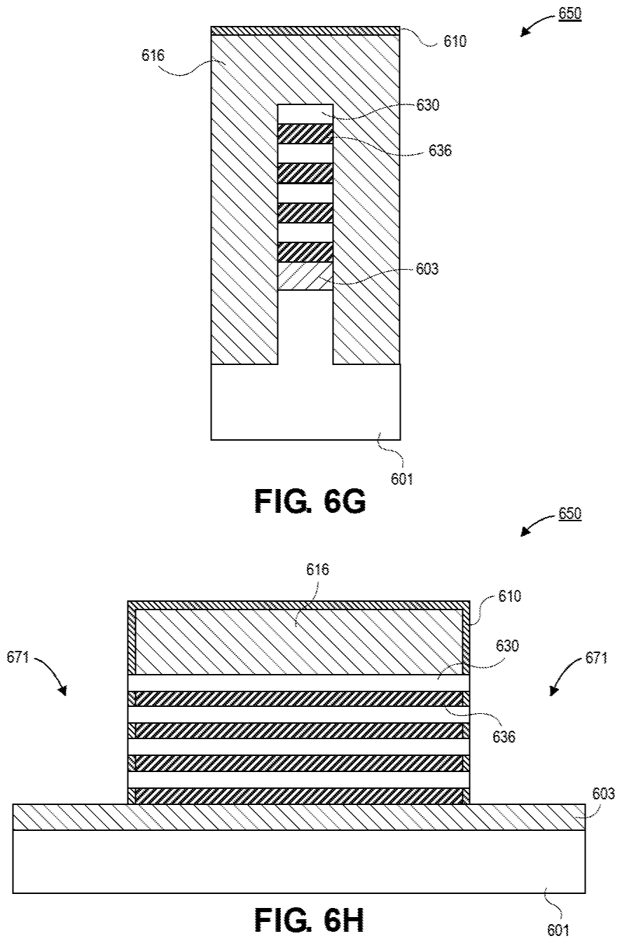

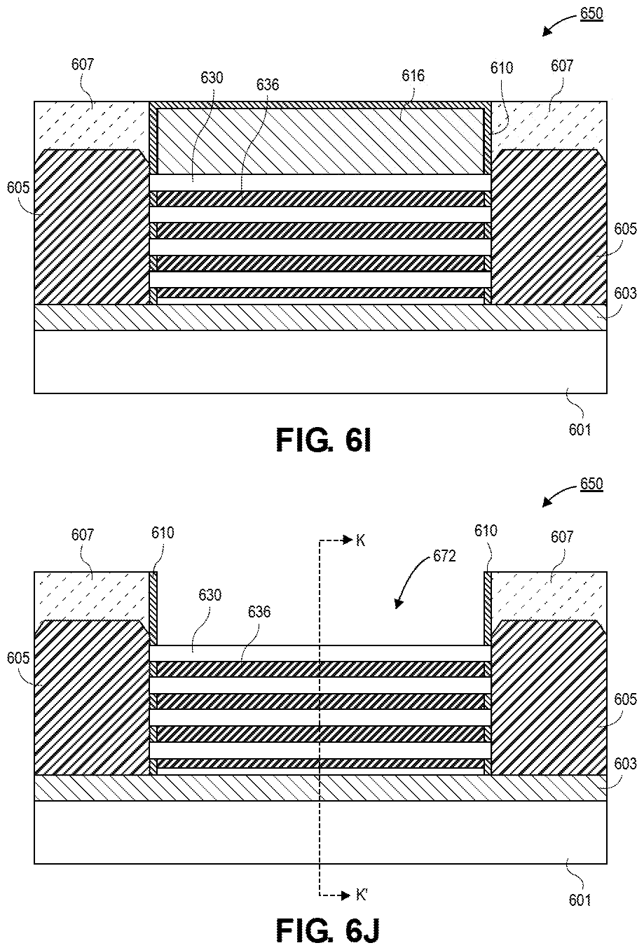

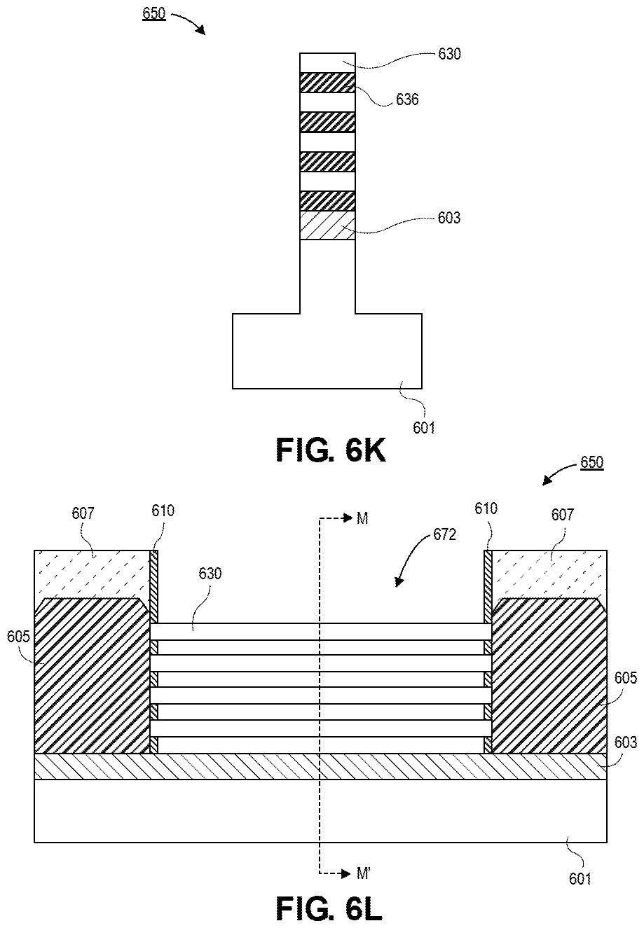

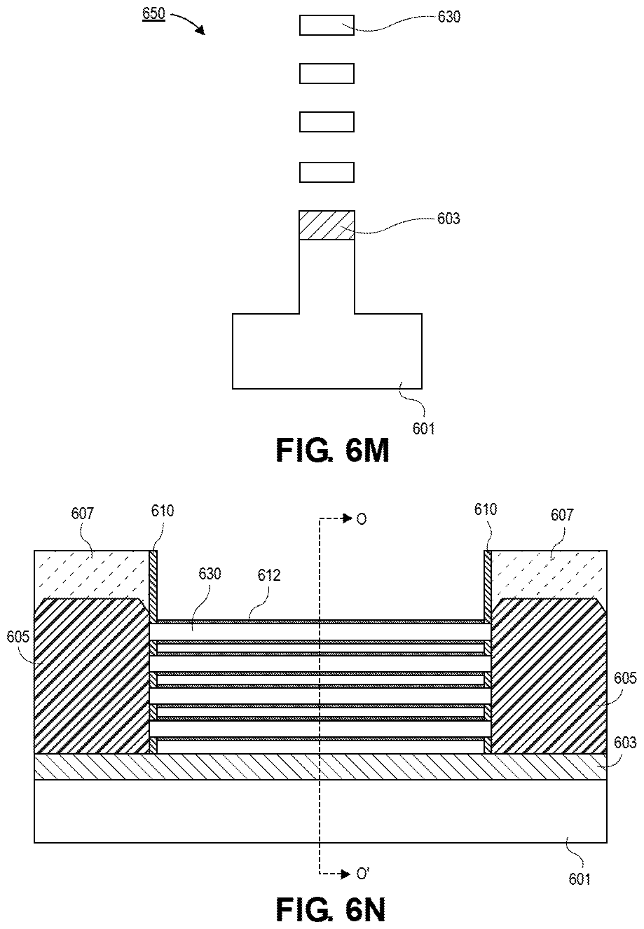

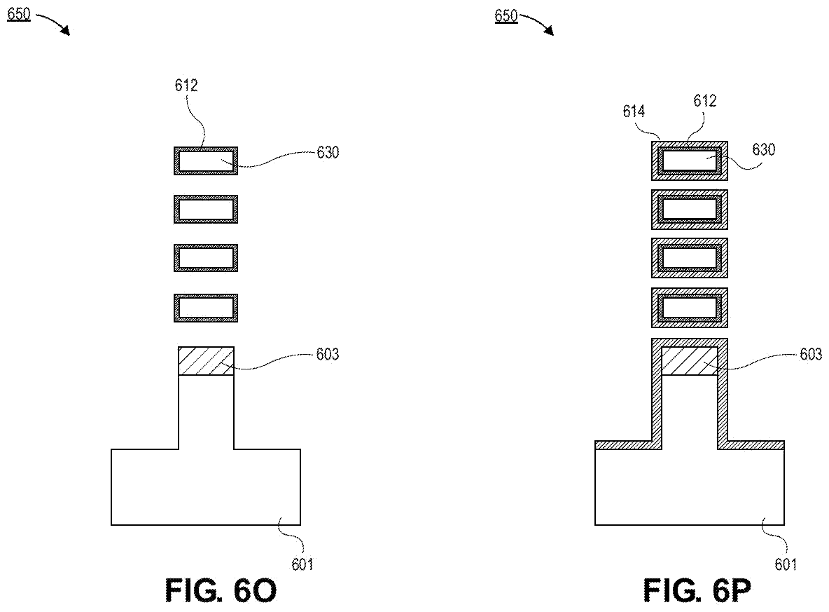

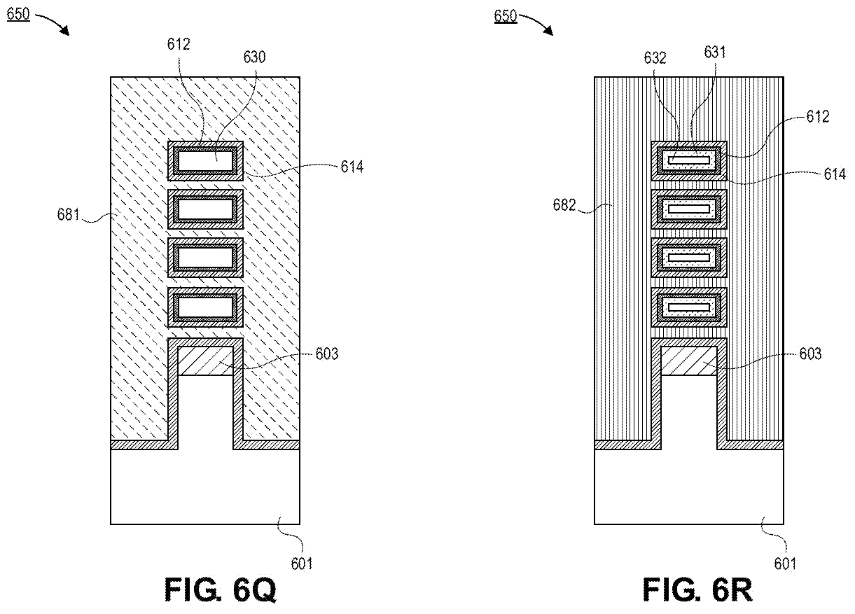

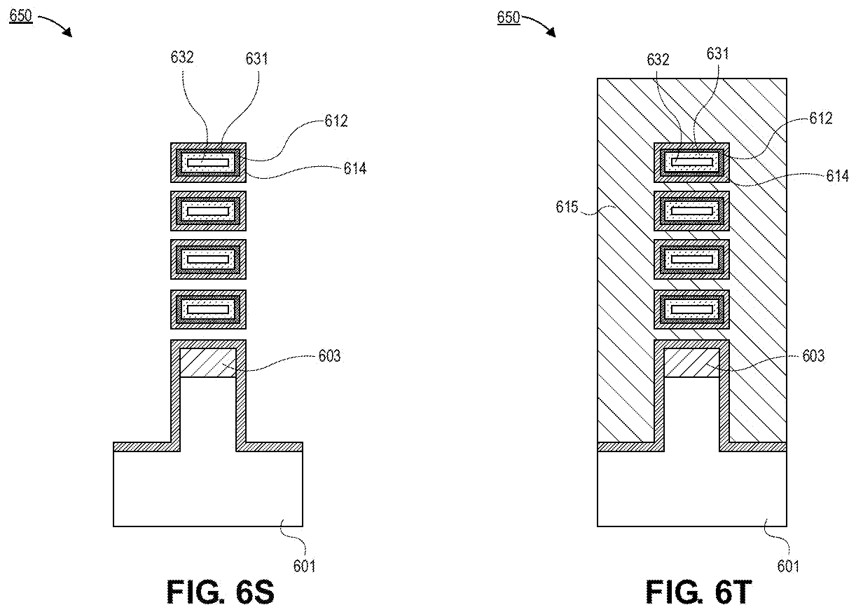

Referring now to FIGS. 6A-6T, a series of illustrations depicting a process for forming a semiconductor device 650 with strained nanoribbon channels is shown, in accordance with an embodiment.

Referring now to FIG. 6A, a perspective view illustration of a semiconductor device 650 is shown, in accordance with an embodiment. The semiconductor device 650 may comprise a substrate 601. The substrate 601 may be similar to the substrates 101 described above. In an embodiment, a stack 660 of alternating channel layers 634 and sacrificial layers 637 is disposed on an insulator layer 603 that is disposed over the substrate 601. In the illustrated embodiment there are four channel layers 634. However, it is to be appreciated that there may be any number of channel layers 634 in the stack 660. In an embodiment, the topmost layer of the stack 660 is a channel layer 634. In other embodiments, the topmost layer of the stack 660 may be a sacrificial layer 637.

In an embodiment, the channel layers 634 are the material chosen for use as the nanoribbon channels of the finished device. The channel layers 634 and sacrificial layers 637 may each be a material such as, but not limited to, silicon, germanium, SiGe, GaAs, InSb, GaP, GaSb, InAlAs, InGaAs, GaSbP, GaAsSb, and InP. In a specific embodiment, the channel layers 634 are silicon and the sacrificial layers 637 are SiGe. In another specific embodiment, the channel layers 634 are germanium, and the sacrificial layers 637 are SiGe. The channel layers 634 and the sacrificial layers 637 may be grown with an epitaxial growth processes.

Referring now to FIG. 6B, a perspective view illustration of the semiconductor device 650 after a plurality of fins 608 are patterned is shown, in accordance with an embodiment. Each fin 608 may comprise a patterned stack 661. Each patterned stack 661 comprises alternating nanoribbon channels 630 and sacrificial layers 636.

Referring now to FIG. 6C, a cross-sectional illustration of the semiconductor device 650 in FIG. 6B along the length of a fin 608 is shown, in accordance with an embodiment. As shown, the patterned stack 661 comprises alternating nanoribbon channels 630 and sacrificial layers 636 over the substrate 601.

Referring now to FIG. 6D, a cross-sectional illustration of the semiconductor device 650 after a sacrificial gate 616 is disposed over the patterned stack 661 is shown, in accordance with an embodiment. The perspective shown in FIG. 6D only illustrates the portion of the sacrificial gate 616 over the top surface of the patterned stack 661. FIG. 6E is a cross-sectional illustration of the semiconductor device 650 in FIG. 6D along line E-E′. As shown, the sacrificial gate 616 wraps down along the sidewalls of the patterned stack 661.

Referring now to FIG. 6F, a cross-sectional illustration of the semiconductor device 650 after a spacer 610 is disposed over the sacrificial gate 616 is shown, in accordance with an embodiment. The spacer 610 may be an insulating layer. The spacer 610 may be disposed over the top surface and sidewalls surfaces of the sacrificial gate 616. FIG. 6G is a cross-sectional illustration of the semiconductor device 650 along line G-G′ of FIG. 6F. As shown, the spacer 610 is over the top surface of the sacrificial gate 616.

Referring now to FIG. 6, a cross-sectional illustration of the semiconductor device 650 after source and drain openings 671 are formed into the stack 661 is shown, in accordance with an embodiment. The openings 671 are positioned outside of the sacrificial gate 616 and the spacers 610. In an embodiment, spacer material 610 may be disposed along end surfaces of the sacrificial layers 636. That is, portions of the nanoribbon channels 630 pass through a thickness of the spacers 610, and the sacrificial layers 636 are laterally recessed and end at the interior surfaces of the spacers 610.

Referring now to FIG. 61, a cross-sectional illustration of the semiconductor device 650 after S/D regions 605 are formed is shown, in accordance with an embodiment. In an embodiment, the S/D regions 605 may be formed with an epitaxial growth process. The S/D regions 605 may be formed with materials and processes such as those described in greater detail above. In an embodiment, an insulator layer 607 may be disposed over the S/D regions 605 to protect the S/D regions 605 from subsequent processing operations.

Referring now to FIG. 6J, a cross-sectional illustration of the semiconductor device 650 after the sacrificial gate 616 is removed to form an opening 672 is shown, in accordance with an embodiment. In an embodiment, the sacrificial gate 616 may be removed with an etching process that is selective to the sacrificial gate 616 while leaving the nanoribbon channels 630 and the sacrificial layers 636 substantially unaltered.

Referring now to FIG. 6K, a cross-sectional illustration of the semiconductor device 650 along line K-K′ of FIG. 6J is shown, in accordance with an embodiment. As shown, removal of the sacrificial gate 616 exposes the sidewalls of the sacrificial layers 636.

Referring now to FIG. 6L, a cross-sectional illustration of the semiconductor device 650 after the sacrificial layer 636 are removed is shown, in accordance with an embodiment. In an embodiment, the sacrificial layers 636 may be removed using any known etchant that is selective to nanoribbon channels 630. In an embodiment, the selectivity is greater than 100:1. In an embodiment where nanoribbon channels 630 are silicon and sacrificial layers 636 are silicon germanium, sacrificial layers 636 are selectively removed using a wet etchant such as, but not limited to, aqueous carboxylic acid/nitric acid/HF solution and aqueous citric acid/nitric acid/HF solution. In an embodiment where nanoribbon channels 630 are germanium and sacrificial layers 636 are silicon germanium, sacrificial layers 636 are selectively removed using a wet etchant such as, but not limited to, ammonium hydroxide (NH₄OH), tetramethylammonium hydroxide (TMAH), ethylenediamine pyrocatechol (EDP), or potassium hydroxide (KOH) solution. In another embodiment, sacrificial layers 636 are removed by a combination of wet and dry etch processes.

Referring now to FIG. 6M, a cross-sectional illustration of the semiconductor device 650 along line M-M′ in FIG. 6L is shown, in accordance with an embodiment. As shown, each of the nanoribbon channels 630 have perimeters that are exposed after the removal of the sacrificial layers 636.

Referring now to FIG. 6N, a cross-sectional illustration of the semiconductor device 650 after a gate dielectric 612 is disposed over the nanoribbon channels 630 is shown, in accordance with an embodiment. In an embodiment, the gate dielectric 612 may be materials such as those described above for gate dielectric 112. In an embodiment, the gate dielectric 612 may be deposited with a conformal deposition process. In such embodiments, the gate dielectric 612 may also be disposed over the interior surfaces of the spacers 610. In other embodiments, the gate dielectric 612 may be disposed with an oxidation process.

Referring now to FIG. 6O, a cross-sectional illustration of the semiconductor device 650 along line 0-0′ in FIG. 6N is shown, in accordance with an embodiment. As shown, the gate dielectric 612 covers an entire perimeter of the nanoribbon channels 630.

Referring now to FIG. 6P, a cross-sectional illustration of the semiconductor device 650 after a gate metal 614 is disposed over the gate dielectric 612 is shown, in accordance with an embodiment. In an embodiment, the gate metal 614 may be a workfunction metal, such as those described above with respect to gate metal 114. In an embodiment, gate metal 614 may be disposed with a conformal deposition process.

Referring now to FIG. 6Q, a cross-sectional illustration of the semiconductor device 650 after a sacrificial polymer 681 is disposed over the gate metal 614 is shown, in accordance with an embodiment. In an embodiment, the sacrificial polymer 681 is a material that is capable of being cured. For example, the curing process may result in cross-linking the sacrificial polymer. In a particular embodiment, the sacrificial polymer 681 may be a carbon hardmask material. The sacrificial polymer 681 completely surrounds the nanoribbon channels 630 and is in direct contact with the gate metal 614.

Referring now to FIG. 6R, a cross-sectional illustration of the semiconductor device 650 after the sacrificial polymer 681 is cured to form a cured sacrificial polymer 682 is shown, in accordance with an embodiment. In an embodiment, the cured sacrificial polymer 682 may be cured with an annealing process. The annealing process may be implemented in an oxygen ambient. The presence of oxygen may increase the degree of cross-linking in some materials. In other embodiments, the anneal may be implemented in an inert ambient (e.g., nitrogen).

The curing of the sacrificial polymer 681 may result in shrinkage of the cured sacrificial polymer 682. That is, the volume of the cured sacrificial polymer 682 may decrease. The shrinkage radially pulls against the gate metal 614. The force against the gate metal 614 is transferred through the gate dielectric 612 and induces a radial tensile strain on the nanoribbon channels 630. For example, the nanoribbon channels 630 may include a strained region 631. In some embodiments, the nanoribbon channels 630 may also include a substantially unstrained region 632 at the core of the nanoribbon channels 630, similar to the embodiment illustrated in FIG. 2A. In other embodiments, the entire semiconductor channel 630 may be a strained region 631 similar to the embodiment illustrated in FIG. 2C.

In an embodiment where the curing process is implemented in an oxygen ambient, the gate metal 614 may have an excess oxygen concentration. The oxygen from the ambient may diffuse through the sacrificial polymer 682 and oxidize portions of the gate metal 614. Particularly, the outer surfaces of the gate metal 614 may have a relatively higher oxygen concentration than an interior surface of the gate metal 614 that is in contact with the gate dielectric 612. For example, the oxygen concentration through a thickness of the gate metal 614 may be similar to the oxygen concentration distribution depicted in FIG. 3B.

Referring now to FIG. 6S, a cross-sectional illustration of the semiconductor device 650 after the cured sacrificial polymer 682 is removed is shown, in accordance with an embodiment. The removal of the cured sacrificial polymer 682 does not release the strain in the nanoribbon channels 630. Particularly, the structure of the semiconductor device 650 (e.g., spacers 610, S/D regions 605, etc.) provides mechanical rigidity that locks in the strain of the nanoribbon channels 630 and does not allow the strained regions 631 to substantially relax after removal of the cured sacrificial polymer 682.

Referring now to FIG. 6T, a cross-sectional illustration of the semiconductor device 650 after a fill metal 615 is disposed over the gate metal 614 is shown, in accordance with an embodiment. In an embodiment, the fill metal 615 may be tungsten or the like.

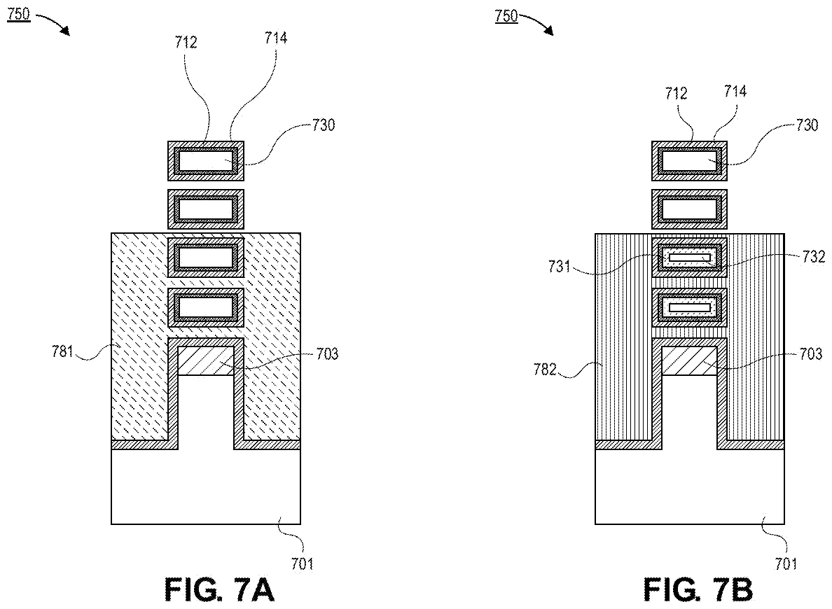

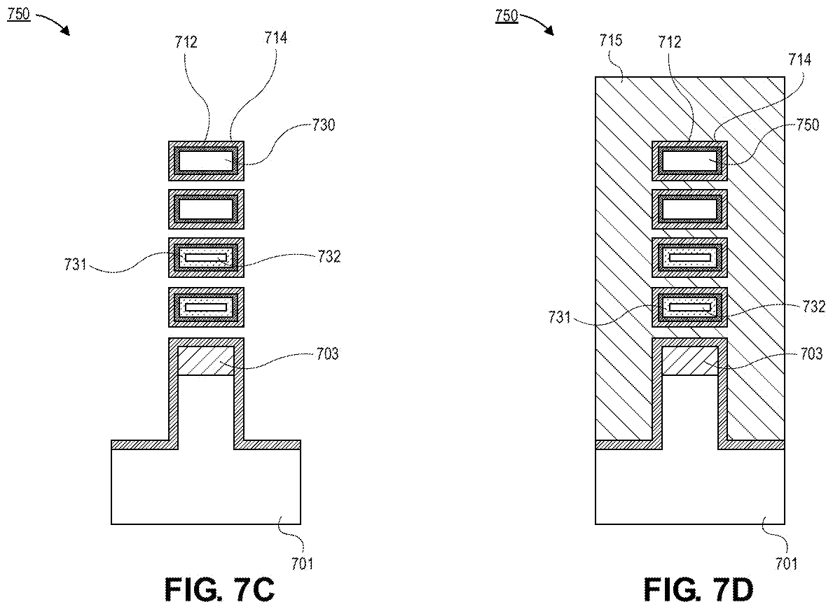

Referring now to FIGS. 7A-7D, a series of cross-sectional illustrations depicting a process for forming a semiconductor device 750 is shown, in accordance with an embodiment. The semiconductor device 750 illustrated in FIGS. 7A-7D may be similar to the semiconductor device 650, with the exception that not all of the nanoribbon channels 730 are strained.

Referring now to FIG. 7A, a cross-sectional illustration of a semiconductor device 750 is shown, in accordance with an embodiment. The semiconductor device 750 may be formed with processes substantially similar to those described above with respect to FIGS. 6A-6P, and therefore, will not be repeated here. That is, the semiconductor device 750 may comprise a substrate 701, an insulator layer 703, and a plurality of vertically stacked nanoribbon channels 730. The nanoribbon channels 730 may be surrounded by a gate dielectric 712 and a gate metal 714.

In an embodiment, a sacrificial polymer 781 is disposed over one or more of the nanoribbon channels 730. Particularly, in the illustrated embodiment, the bottom two nanoribbon channels 730 are surrounded by the sacrificial polymer 781, and the top two nanoribbon channels 730 are not covered by a sacrificial polymer 781.

Referring now to FIG. 7B, a cross-sectional illustration of the semiconductor device 750 after the sacrificial polymer 781 is cured to form a cured sacrificial polymer 782 is shown, in accordance with an embodiment. The curing process may be substantially similar to the curing process described above with respect to FIG. 6R. As shown, the nanoribbon channels 730 that are surrounded by the cured sacrificial polymer 782 are strained. For example, strained regions 731 are formed in the bottom two nanoribbon channels 730. The uncovered nanoribbon channels 730 remain substantially unstrained. That is, the strain within the nanoribbon channels 730 of a single transistor may be non-uniform in some embodiments.

Referring now to FIG. 7C, a cross-sectional illustration of the semiconductor device 750 after the cured sacrificial polymer 782 is removed is shown, in accordance with an embodiment. Similar to above, removal of the cured sacrificial polymer 782 does not substantially release the strain of the strained regions 731. In an embodiment, the strained nanoribbon channels 730 in FIG. 7C may be similar to the strained nanoribbon channels in FIG. 2A (e.g., comprising a strained region 731 and an unstrained region 732) or FIG. 2C (e.g., comprising a strained region 731 only).

Referring now to FIG. 7D, a cross-sectional illustration of the semiconductor device 750 after a fill metal 715 is disposed over the gate metal 714 is shown, in accordance with an embodiment. In an embodiment, the fill metal 715 may be tungsten or the like.

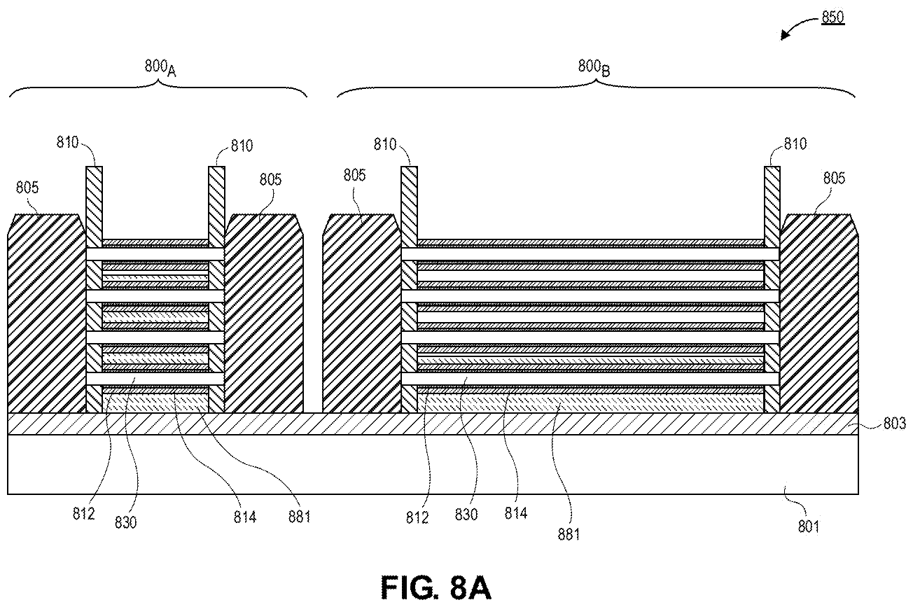

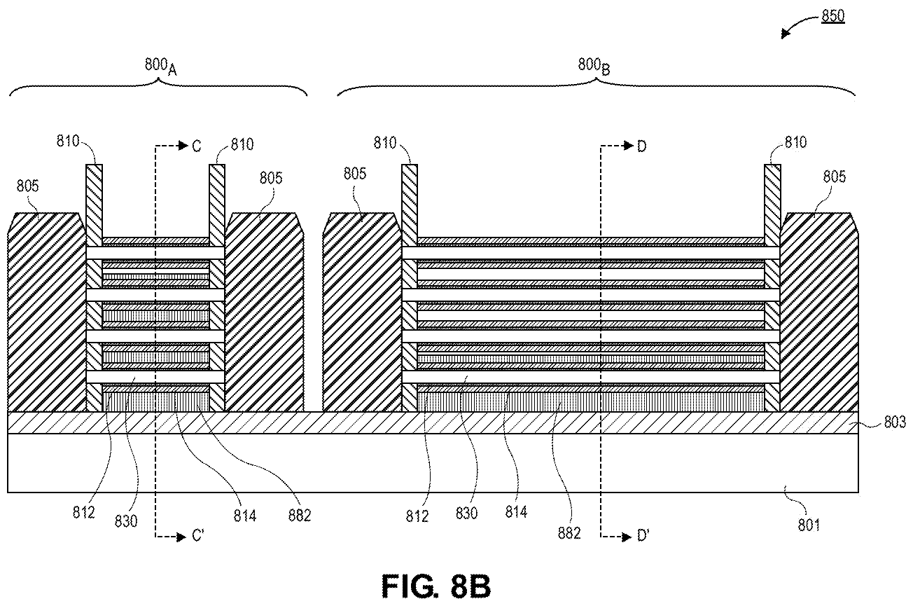

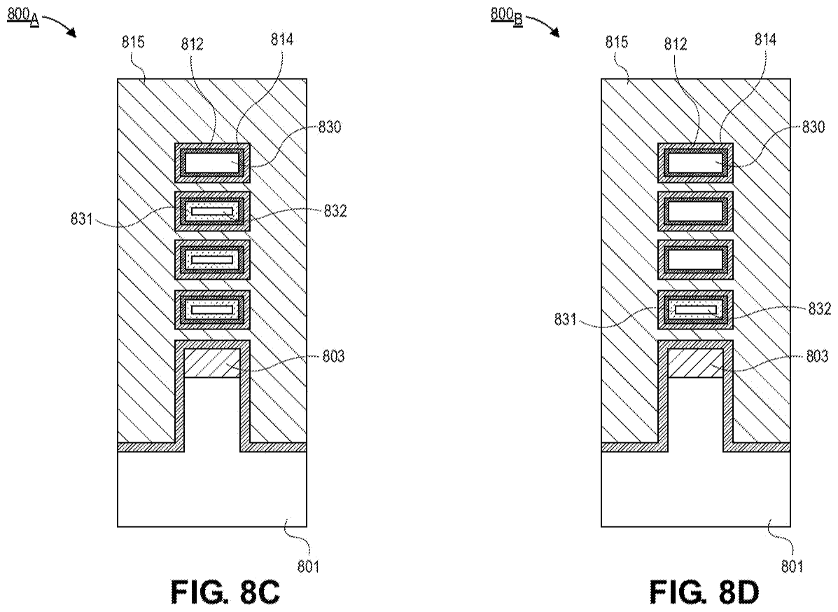

Referring now to FIGS. 8A-8D, a series of cross-sectional illustrations depicting a process for forming a semiconductor device 850 is shown, in accordance with an embodiment. FIGS. 8A-8D include a pair of transistors 800_{A} and 800_{B}. In an embodiment, the number of strained nanoribbon channels 830 in each transistor 800_{A} and 800_{B} is non-uniform.

Referring now to FIG. 8A, a cross-sectional illustration of a semiconductor device 850 is shown, in accordance with an embodiment. The semiconductor device 850 may comprise a first transistor 800_{A} and a second transistor 800_{B} formed over a substrate 801 and an insulator layer 803. The transistors 800_{A} and 800_{B} may comprise S/D regions 805 and nanoribbon channels 830 between the S/D regions 805. The nanoribbon channels 830 may pass through spacers 810. In an embodiment, the nanoribbon channels 830 may be surrounded by a gate dielectric 812 and a gate metal 814.

In an embodiment, a sacrificial polymer 881 may be disposed around the nanoribbon channels 830 between the spacers 810. As shown, the sacrificial polymer 881 in the first transistor 800_{A} may cover a different number of nanoribbon channels 830 than the sacrificial polymer 881 in the second transistor 800_{B}. For example, a patterning process may be used to form the sacrificial polymers 881 with non-uniform thicknesses. In the particular embodiment illustrated in FIG. 8A, the first transistor 800_{A} includes three nanoribbon channels 830 that are covered by the sacrificial polymer 881, and the second transistor 800_{B} includes one semiconductor channel 830 that is covered by the sacrificial polymer 881. In other embodiments, the first transistor 800_{A} may have one or more strained nanoribbon channels 830 and the second transistor 800_{B} will have no strained nanoribbon channels 830. That is, there may not be any of the sacrificial polymer 881 disposed over the nanoribbon channels 830 of the second transistor 800_{B} in some embodiments.

Referring now to FIG. 8B, a cross-sectional illustration of the semiconductor device 850 after the sacrificial polymer 881 is cured to form a cured sacrificial polymer 882 is shown, in accordance with an embodiment. In an embodiment, the curing process may be substantially similar to the process described above with respect to FIG. 6R.

Referring now to FIGS. 8C and 8D, a pair of cross-sectional illustrations of the first transistor 800_{A} and the second transistor 800_{B} after the cured sacrificial polymer 882 is removed and a fill metal 815 is disposed are shown, respectively, in accordance with an embodiment. As shown in FIG. 8C, the first transistor 800_{A} includes three nanoribbon channels 830 that include a strained region 831. As shown in FIG. 8D, the second transistor 800_{B} includes one semiconductor channel 830 that includes a strained region 831. In an embodiment, the strained nanoribbon channels 830 in FIGS. 8C and 8D may be similar to the strained nanoribbon channels in FIG. 2A (i.e., including a strained region 831 and an unstrained region 832) or FIG. 2C (e.g., including only a strained region 831).

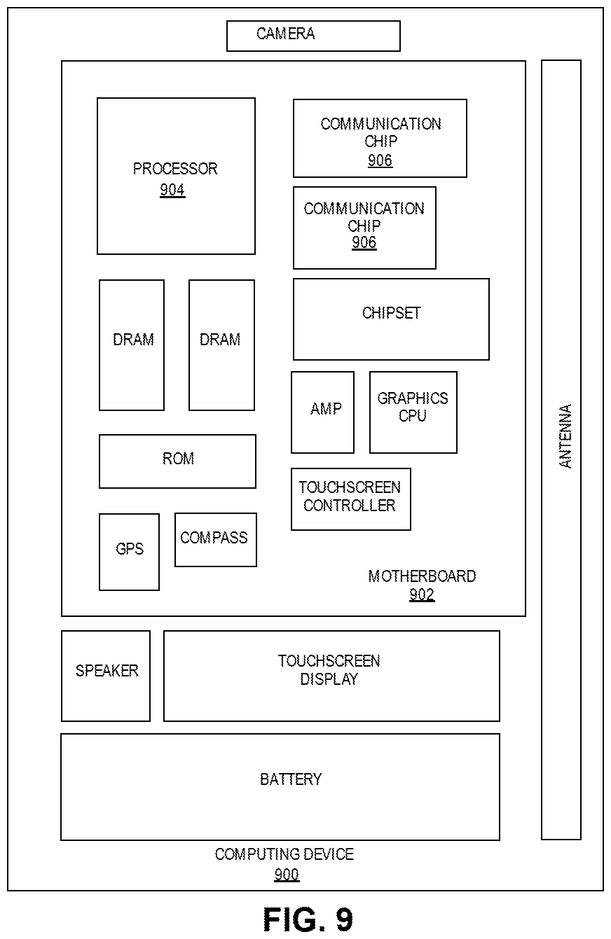

FIG. 9 illustrates a computing device 900 in accordance with one implementation of an embodiment of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In an embodiment, the integrated circuit die of the processor 904 may comprise a semiconductor channel with radial tensile strain, as described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In an embodiment, the integrated circuit die of the communication chip 906 may comprise a semiconductor channel with radial tensile strain, as described herein.

In further implementations, another component housed within the computing device 900 may comprise a semiconductor channel with radial tensile strain, as described herein.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

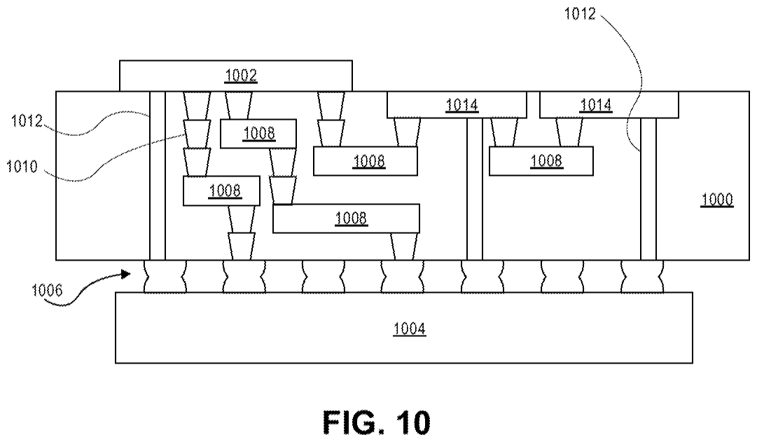

FIG. 10 illustrates an interposer 1000 that includes one or more embodiments of the disclosure. The interposer 1000 is an intervening substrate used to bridge a first substrate 1002 to a second substrate 1004. The first substrate 1002 may be, for instance, an integrated circuit die. The second substrate 1004 may be, for instance, a memory module, a computer motherboard, or another integrated circuit die. In an embodiment, one of both of the first substrate 1002 and the second substrate 1004 may comprise a semiconductor channel with radial tensile strain, in accordance with embodiments described herein. Generally, the purpose of an interposer 1000 is to spread a connection to a wider pitch or to reroute a connection to a different connection. For example, an interposer 1000 may couple an integrated circuit die to a ball grid array (BGA) 1006 that can subsequently be coupled to the second substrate 1004. In some embodiments, the first and second substrates 1002/1004 are attached to opposing sides of the interposer 1000. In other embodiments, the first and second substrates 1002/1004 are attached to the same side of the interposer 1000. And in further embodiments, three or more substrates are interconnected by way of the interposer 1000.

The interposer 1000 may be formed of an epoxy resin, a fiberglass-reinforced epoxy resin, a ceramic material, or a polymer material such as polyimide. In further implementations, the interposer 1000 may be formed of alternate rigid or flexible materials that may include the same materials described above for use in a semiconductor substrate, such as silicon, germanium, and other group III-V and group IV materials

The interposer 1000 may include metal interconnects 1008 and vias 1010, including but not limited to through-silicon vias (TSVs) 1012. The interposer 1000 may further include embedded devices 1014, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1000. In accordance with embodiments of the disclosure, apparatuses or processes disclosed herein may be used in the fabrication of interposer 1000.

Thus, embodiments of the present disclosure may comprise a semiconductor channel with radial tensile strain, and the resulting structures.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a semiconductor device, comprising: a source; a drain; a semiconductor channel between the source and the drain, wherein the semiconductor channel has a non-uniform strain through a thickness of the semiconductor channel; and a gate stack around the semiconductor channel.

Example 2: the semiconductor device of Example 1, wherein a first strain at a surface of the semiconductor channel is greater than a second strain within the semiconductor channel.

Example 3: the semiconductor device of Example 2, wherein the second strain is approximately 0%.

Example 4: the semiconductor device of Example 2, wherein the second strain is greater than approximately 0%.

Example 5: the semiconductor device of Examples 2-4, wherein the first strain is approximately 0.5% or greater.

Example 6: the semiconductor device of Examples 1-3, wherein the non-uniform strain is a tensile strain.

Example 7: the semiconductor device of Examples 1-6, wherein the gate stack comprises: a gate dielectric on the semiconductor channel; and a gate metal on the gate dielectric.

Example 8: the semiconductor device of Example 7, wherein the gate metal comprises oxygen.

Example 9: the semiconductor device of Example 8, wherein a first concentration of oxygen at a surface of the gate metal facing away from the gate dielectric is greater than a second concentration of oxygen at a surface of the gate metal facing the gate dielectric.

Example 10: the semiconductor device of Examples 1-9, wherein the semiconductor channel is a nanowire or a nanoribbon.

Example 11: a semiconductor device, comprising: a source; a drain; a plurality of semiconductor channels arranged in a vertical stack between the source and the drain, wherein individual ones of the semiconductor channels comprise a radial tensile strain; a gate dielectric surrounding individual semiconductor channels; and a gate metal surrounding the gate dielectric.

Example 12: the semiconductor device of Example 11, wherein a first semiconductor channel of the plurality of semiconductor channels has a first maximum tensile strain, and a second semiconductor channel of the plurality of semiconductor channels has a second maximum tensile strain, wherein the first maximum tensile strain is greater than the second maximum tensile strain.

Example 13: the semiconductor device of Example 12, wherein the first semiconductor channel is below the second semiconductor channel.

Example 14: the semiconductor device of Example 12 or Example 13, wherein the first maximum tensile strain is approximately 0.5% or greater.

Example 15: the semiconductor device of Examples 11-14, wherein the gate metal comprises oxygen.

Example 16: the semiconductor device of Example 15, wherein an oxygen concentration along a line from an outer surface of the gate dielectric to a center of an individual one of the semiconductor channels, comprises: a decreasing oxygen concentration form the outer surface of the gate dielectric to an inner surface of the gate dielectric; an increasing oxygen concentration through a thickness of the gate dielectric; and a decreasing oxygen concentration into the individual one of the semiconductor channels.

Example 17: the semiconductor device of Examples 11-16, wherein individual semiconductor channels are nanowires or nanoribbons.

Example 18: a method of forming a semiconductor device, comprising: forming a semiconductor channel; disposing a gate dielectric around the semiconductor channel; disposing a gate metal around the gate dielectric; disposing a sacrificial polymer around the gate metal; annealing the sacrificial polymer, wherein annealing the sacrificial polymer reduces a volume of the sacrificial polymer and induces a tensile strain into the semiconductor channel; and removing the sacrificial polymer.

Example 19: the method of Example 18, wherein the sacrificial polymer is annealed in an oxygen ambient.

Example 20: the method of Example 19, wherein the annealing results in oxygen incorporated into the gate metal.

Example 21: the method of Examples 18-20, wherein the sacrificial polymer is annealed in an inert ambient.

Example 22: the method of Examples 18-21, wherein the tensile strain is approximately 0.5% or greater.

Example 23: the method of Examples 18-22, wherein the semiconductor channel is a nanowire or a nanoribbon.

Example 24: an electronic device, comprising: a board; a semiconductor package coupled to the board; and a die coupled to the semiconductor package, wherein the die comprises: a source; a drain; a semiconductor channel between the source and the drain, wherein the semiconductor channel comprises a radial tensile strain; and a gate stack around the semiconductor channel.

Example 25: the electronic device of Example 24, wherein the semiconductor channel is a nanowire or a nanoribbon.

What is claimed is:

1. A semiconductor device, comprising:
a source;
a drain;
a semiconductor channel between the source and the drain, wherein the semiconductor channel has a non-uniform strain through a thickness of the semiconductor channel; and
a gate stack around the semiconductor channel.

2. The semiconductor device of claim 1, wherein a first strain at a surface of the semiconductor channel is greater than a second strain within the semiconductor channel.

3. The semiconductor device of claim 2, wherein the second strain is approximately 0%.

4. The semiconductor device of claim 2, wherein the second strain is greater than approximately 0%.

5. The semiconductor device of claim 2, wherein the first strain is approximately 0.5% or greater.

6. The semiconductor device of claim 1, wherein the non-uniform strain is a tensile strain.

7. The semiconductor device of claim 1, wherein the gate stack comprises:
a gate dielectric on the semiconductor channel; and
a gate metal on the gate dielectric.

8. The semiconductor device of claim 7, wherein the gate metal comprises oxygen.

9. The semiconductor device of claim 8, wherein a first concentration of oxygen at a surface of the gate metal facing away from the gate dielectric is greater than a second concentration of oxygen at a surface of the gate metal facing the gate dielectric.

10. The semiconductor device of claim 1, wherein the semiconductor channel is a nanowire or a nanoribbon.

11. A semiconductor device, comprising:
a source;
a drain;
a plurality of semiconductor channels arranged in a vertical stack between the source and the drain, wherein individual ones of the semiconductor channels comprise a radial tensile strain;
a gate dielectric surrounding individual semiconductor channels; and
a gate metal surrounding the gate dielectric.

12. The semiconductor device of claim 11, wherein a first semiconductor channel of the plurality of semiconductor channels has a first maximum tensile strain, and a second semiconductor channel of the plurality of semiconductor channels has a second maximum tensile strain, wherein the first maximum tensile strain is greater than the second maximum tensile strain.

13. The semiconductor device of claim 12, wherein the first semiconductor channel is below the second semiconductor channel.

14. The semiconductor device of claim 12, wherein the first maximum tensile strain is approximately 0.5% or greater.

15. The semiconductor device of claim 11, wherein the gate metal comprises oxygen.

16. The semiconductor device of claim 15, wherein an oxygen concentration along a line from an outer surface of the gate dielectric to a center of an individual one of the semiconductor channels, comprises:
a decreasing oxygen concentration form the outer surface of the gate dielectric to an inner surface of the gate dielectric;
an increasing oxygen concentration through a thickness of the gate dielectric; and
a decreasing oxygen concentration into the individual one of the semiconductor channels.

17. The semiconductor device of claim 11, wherein individual semiconductor channels are nanowires or nanoribbons.

18. A method of forming a semiconductor device, comprising:
forming a semiconductor channel;
disposing a gate dielectric around the semiconductor channel;
disposing a gate metal around the gate dielectric;
disposing a sacrificial polymer around the gate metal;
annealing the sacrificial polymer, wherein annealing the sacrificial polymer reduces a volume of the sacrificial polymer and induces a tensile strain into the semiconductor channel; and
removing the sacrificial polymer.

19. The method of claim 18, wherein the sacrificial polymer is annealed in an oxygen ambient.

20. The method of claim 19, wherein the annealing results in oxygen incorporated into the gate metal.

21. The method of claim 18, wherein the sacrificial polymer is annealed in an inert ambient.

22. The method of claim 18, wherein the tensile strain is approximately 0.5% or greater.

23. The method of claim 18, wherein the semiconductor channel is a nanowire or a nanoribbon.

24. An electronic device, comprising:
a board;
a semiconductor package coupled to the board; and
a die coupled to the semiconductor package, wherein the die comprises:
a source;
a drain;
a semiconductor channel between the source and the drain, wherein the semiconductor channel comprises a radial tensile strain; and
a gate stack around the semiconductor channel.

25. The electronic device of claim 24, wherein the semiconductor channel is a nanowire or a nanoribbon.
